(19) United States
(12) Patent Application Publication
(10) Pub. No.: US 2012/0247525 A1
(43) Pub. Date: Oct. 4, 2012

(54) TUNGSTEN-TITANIUM-PHOSPHATE MATERIALS AND METHODS FOR MAKING AND USING THE SAME

(76) Inventors: Bruce Gardiner Aitken, Corning, NY (US); Lisa Anne Moore, Corning, NY (US)

(21) Appl. No.: 13/077,147

(22) Filed: Mar. 31, 2011

(51) Int. Cl. H01L 35/28; H01L 35/14; H01B 1/08

(52) U.S. Cl. 136/205; 252/520.21

(57) ABSTRACT

Tungsten-titanium-phosphate materials and methods of making and using the same. The Tungsten-titanium-phosphate materials comprise about 20 to 60 actual mol % WO₃, about 10 to 40 actual mol % TiO₂, and about 15 to 40 actual mol % P₂O₅

### FIELD OF THE DISCLOSURE

Disclosed herein are novel tungsten-titanium-phosphate materials, and novel methods for making tungsten-titanium-phosphate glass-ceramic materials. The disclosure further relates to methods for generating electricity from waste heat, said methods comprising applying a module comprising at least one tungsten-titanium-phosphate material to a source of waste heat.

### BACKGROUND

High temperature thermoelectric materials are an enabling component for electricity generation via waste heat recovery. In various applications, it can be advantageous for thermoelectric materials to exhibit a high Seebeck coefficient (S), high electrical conductivity (σ), and low thermal conductivity (κ) as expressed by its figure-of-merit, ZT=(S²σT)/κ, where T is temperature.

Much of the focus in the study of thermoelectric materials has been on outer space applications where the peak efficiency of the device needs to be at very low temperatures. With the recent focus on energy conservation, there exists a need for thermoelectric materials for use in higher temperature applications such as automotive (exhaust) and industrial waste heat recovery. Such materials may have peak efficiencies at elevated temperatures.

The inventors have now discovered novel tungsten-titanium-phosphate materials, as well as novel methods of making tungsten-titanium-phosphate glass-ceramic materials. The inventors have also discovered novel methods for generating electricity from waste heat, said methods comprising applying a module comprising at least one tungsten-titanium-phosphate material to a source of waste heat.

### SUMMARY

In accordance with the detailed description and various exemplary embodiments described herein, the disclosure relates to tungsten-titanium-phosphate materials comprising about 20 to 60 actual mol % WO₃, about 10 to 40 actual mol % TiO₂, and about 15 to 40 actual mol % P₂O₅, wherein the tungsten-titanium-phosphate materials may further comprise silica and/or at least one dopant. In further embodiments, the tungsten-titanium-phosphate materials may be characterized by one or more property, independently or in any combination, including the figure-of-merit (ZT), Seebeck coefficient (S), electrical conductivity (σ), thermal conductivity (κ), and power factor (S²σ). In various exemplary embodiments, said tungsten-titanium-phosphate materials may be glass-ceramic materials.

The disclosure also relates to methods for generating electricity from waste heat, said methods comprising applying a module comprising at least one tungsten-titanium-phosphate material to a source of waste heat, wherein the at least one tungsten-titanium-phosphate material comprises about 20 to 60 actual mol % WO₃, about 10 to 40 actual mol % TiO₂, and about 15 to 40 actual mol % P₂O₅.

The disclosure also relates to methods of making tungsten-titanium-phosphate glass-ceramic materials comprising: mixing batch ingredients including sources of WO₃, TiO₂, and P₂O₅ to form a batch mixture, melting the batch mixture, quenching the melted batch mixture to glass, and ceramming the glass. In further embodiments, ceramming the glass may comprise one or more heating stages.

### BRIEF DESCRIPTION OF THE DRAWINGS

The accompanying drawings are included to provide a further understanding of the disclosure, and are incorporated in and constitute a part of this specification. The drawings are not intended to be restrictive of the invention as claimed, but rather illustrate embodiments of the disclosure and, together with the description, serve to explain the principles described herein.

FIG. 1 depicts electrical conductivity as a function of temperature for materials according to one embodiment and as described in Example 1;

FIG. 2 depicts Seebeck coefficient as a function of temperature for materials according to one embodiment and as described in Example 1;

FIG. 3 depicts thermal conductivity as a function of temperature for materials according to one embodiment and as described in Example 1;

FIG. 4 depicts figure-of-merit as a function of temperature for materials according to one embodiment and as described in Example 1;

FIG. 5 depicts x-ray diffraction patterns of a material according to one embodiment and as described in Example 1;

FIG. 6 depicts x-ray diffraction patterns of a material according to one embodiment and as described in Example 1;

FIG. 7 depicts x-ray diffraction patterns of a material according to one embodiment and as described in Example 1; and

FIG. 8 depicts x-ray diffraction patterns of a material according to one embodiment and as described in Example 2.

### DETAILED DESCRIPTION

It is to be understood that both the foregoing general description and the following detailed description are exemplary and explanatory only, and are not restrictive of the invention as claimed.

As used herein, the articles “the,” “a,” or “an” mean “at least one,” and should not be limited to “only one” unless explicitly indicated to the contrary. Thus, for example, the use of “the tungsten-titanium-phosphate material” or “a tungsten-titanium-phosphate material” is intended to mean “at least one tungsten-titanium-phosphate material.”

The disclosure relates to, in various embodiments, tungsten-titanium-phosphate materials comprising about 20 to 60 actual mol % WO₃, about 10 to 40 actual mol % TiO₂, and about 15 to 40 actual mol % P₂O₅. In further embodiments, the tungsten-titanium-phosphate materials may comprise about 20 to 24 actual mol % WO₃ and/or may comprise about 15 to 24 actual mol % P₂O₅. As used herein, the term “actual mol %” refers to the mol % calculated from the weight fractions determined by conventional wet chemical analysis. Additionally, the actual mol % values are based on measured concentrations of the elements, e.g., W, Ti, and P, and reported as being in 100% fully oxidized states, e.g., WO₃, TiO₂, and P₂O₅. It should be noted, however, that some reduction may occur, and the measured elements may not be in fully oxidized states, e.g., tungsten may be present as W⁺⁵ and/or W⁺⁶.

In various exemplary embodiments, the tungsten-titanium-phosphate material may further comprise silica, SiO₂. For example, the material may comprise from about 1 to 15 actual mol % SiO₂, such as about 5 to 15 actual mol % SiO₂.

In further exemplary embodiments, the tungsten-titanium-phosphate material of the disclosure may also comprise at least one dopant. In various embodiments, the dopant may be chosen from alkali metals and transition metals. For example, the dopant may be chosen from, but is not limited to, Li, Na, K, Rb, Cs, V, Cr, Mn, Fe, Co, Ni, Cu, Mo, Nb, Al and Zr. In various embodiments, the dopant may be added to the batch mixture as carbonates, phosphates, or oxides. In various embodiments, the material may comprise from about 0.1 to 15 actual mol % dopant, such as about 1 to 13 actual mol %, or about 3 to 10 actual mol % dopant.

In various embodiments of the disclosure, the tungsten-titanium-phosphate materials may have an electrical conductivity of at least about 100 S/m at 560K, such as at least about 500 S/m, at least about 1,000 S/m, at least about 5,000 S/m, at least about 10,000 S/m, at least about 15,000 S/m, and at least about 25,000 S/m at 560K. In various additional embodiments, the tungsten-titanium-phosphate materials may have an electrical conductivity of at least about 1,000 S/m at 1050K, such as at least about 2000 S/m, at least about 5000 S/m, at least about 10,000 S/m, at least about 15,000 S/m, and at least about 50,000 S/m at 1050 K. It is within the ability of one skilled in the art to determine the electrical conductivity of the tungsten-titanium-phosphate materials using conventional methods.

In various embodiments of the disclosure, the tungsten-titanium-phosphate materials according to the disclosure may have a thermal conductivity of less than about 5 W/m·K at 560K, such as less than about 3 W/m·K, and less than about 2 W/m·K at 560K. In various additional embodiments, the tungsten-titanium-phosphate materials may have a thermal conductivity of less than about 5 W/m·K at 1050K, such as less than about 3 W/m·K, and less than about 2 W/m·K at 1050K. It is within the ability of one skilled in the art to determine the thermal conductivity of the tungsten-titanium-phosphate materials using conventional methods.

Seebeck coefficients for the tungsten-titanium-phosphate materials of the present disclosure are negative, indicating n-type behavior. In various embodiments, the tungsten-titanium-phosphate materials of the disclosure may have a Seebeck coefficient (S) of at least about 20 μV/K, absolute, at 560K, such as at least about 30 μV/K, at least about 40 μV/K, at least about 50 μV/K, at least about 60 μV/K, at least about 70 μV/K, at least about 80 μV/K, at least about 90 μV/K, and at least about 100 μV/K, absolute, at 560K. In various additional embodiments, the tungsten-titanium-phosphate materials may have a Seebeck coefficient of at least about 40 μV/K, absolute, at 1050K, such as at least about 50 μV/K, at least about 60 μV/K, at least about 70 μV/K, at least about 80 μV/K, at least about 90 μV/K, at least about 100 μV/K, and at least about 110 μV/K, absolute, at 1050 K. It is within the ability of one skilled in the art to determine the Seebeck coefficient of the tungsten-titanium-phosphate materials using conventional methods.

The figure-of-merit (ZT) is a measure of the potential of a thermoelectric material for energy conversion, and may be determined using the following formula:

$$ZT = \frac{{S}^{2} σ T}{κ}$$

where S is the Seebeck coefficient (V/K), σ is the electrical conductivity (S/m=1/Ω·m), T is temperature (K), and κ is thermal conductivity (W/m·K).

In various embodiments of the disclosure, the tungsten-titanium-phosphate material may have a ZT of at least about 0.0001 at 560K, such as at least about 0.001, at least about 0.01, at least about 0.1, at least about 0.3, or at least about 0.5. In additional embodiments, the tungsten-titanium-phosphate material may have a ZT of at least about 0.001 at 1050K, such as at least about 0.01, at least about 0.1, at least about 0.3, or at least about 0.5. It is within the ability of one skilled in the art to determine the ZT of the tungsten-titanium-phosphate materials using conventional methods.

The Power Factor (PF) may be determined by the following formula:

PF=S²σ

where S is the Seebeck coefficient (V/K), and σ is the electrical conductivity (S/m=1/Ω·m).

In various embodiments of the disclosure, the tungsten-titanium-phosphate material may have a PF of at least about 1.0E-07 W/m·K² at 560K, such as at least about 5.0E-07, at least about 1.0E-06 W/m·K², at least about 5.0E-06 W/m·K², or at least about 1.0E-05 W/m·K² at 560K. In various additional embodiments, the tungsten-titanium-phosphate materials may have a PF of at least about 1.0E-06 W/m·K² at 1050K, such as at least about 5.0E-06 W/m·K², at least about 1.0E-05 W/m·K², at least about 5.0E-05 W/m·K², or at least about 1.0E-04 W/m·K² at 1050K. It is within the ability of one skilled in the art to determine the PF of the tungsten-titanium-phosphate materials using conventional methods.

The tungsten-titanium-phosphate materials of the disclosure may be glasses, ceramics, or glass-ceramic materials. The term “glass-ceramic materials,” and variations thereof, is intended to mean that the materials transition from a glassy or amorphous phase to substantially one or more crystalline phases after heating. In at least one embodiment, the material consist of a glass-ceramic.

The disclosure further relates, in various embodiments, to methods for generating electricity from waste heat, said methods comprising applying a module comprising at least one tungsten-titanium-phosphate material to a source of waste heat.

As used herein, “waste heat,” and variations thereof, is intended to include any form of heat or temperature difference. As used herein, “waste heat source,” and variations thereof, is intended to include any device, object, or process that creates or generates heat and may, in various embodiments, include automotive and industrial processes, such as automotive exhaust.

As used here, the term “module,” and variations thereof, is intended to include any component or device capable of creating voltage in the presence of a temperature differential or waste heat. The module of the disclosed methods comprises at least one tungsten-titanium-phosphate material.

The disclosure also relates to methods of making tungsten-titanium-phosphate glass-ceramic materials, said methods comprising mixing batch ingredients including sources of WO₃, TiO₂, and P₂O₅ to form a batch mixture, melting the batch mixture, quenching the melted batch mixture to glass, and ceramming the glass.

As used herein, the term “tungsten-titanium-phosphate glass-ceramic material,” and variations thereof, is intended to mean tungsten-titanium-phosphate materials that transition from a glassy or amorphous phase to substantially one or more crystalline phases after ceramming.

In various embodiments of the disclosed methods of making tungsten-titanium-phosphate glass-ceramic materials, the tungsten-titanium-phosphate glass-ceramic material may comprise about 20 to 60 actual mol % WO₃, about 10 to 40 actual mol % TiO₂, and about 15 to 40 actual mol % P₂O₅. In further embodiments, the tungsten-titanium-phosphate glass-ceramic materials may comprise about 20 to 24 actual mol % WO₃ and/or may comprise about 15 to 24 actual mol % P₂O₅.

As used herein, the term “batch ingredients,” and variations thereof, is intended to mean materials, oxides and/or compounds that may be used in making the tungsten-titanium-phosphate glass-ceramic materials described herein. The batch ingredients may include, but are not limited to, for example, sources of WO₃ chosen from, for example, tungsten trioxide, sources of TiO₂ chosen from, for example, titanium dioxide and titanium (III) oxide, and sources of P₂O₅ chosen from, for example, ammonium phosphate. Since it is may be advantageous for the material to be in a reduced state, batch ingredients that serve to reduce the oxidation states of the components, but which are not intended to remain in the material after melting, may be added to the batch. Such reducing agents may include, for example, carbon or sugar. The batch ingredients may be provided as powdered materials.

The batch ingredients may be mixed together to form a batch mixture. The resulting batch mixture is, in at least some embodiments, a substantially homogeneous mixture of the batch ingredients. It is within the ability of one of skill in the art to determine the appropriate steps and conditions for mixing the batch ingredients to achieve a substantially homogeneous batch mixture having the desired degree of homogeneity. For example, in at least one embodiment, the batch ingredients may be mixed in a Turbula® mixer or using a ball mill.

The batch mixture may be melted by any process known to those of skill in the art. By way of example, the mixture may be placed in a covered silica crucible and heated in a furnace at a temperature and time sufficient to completely melt the batch materials. In one exemplary embodiment, the silica crucible may be heated at a temperature of about 1525° C. for about 2 hours.

The melted batch mixture may be quenched to glass by any process known to those of skill in the art. By way of example, the mixture may be poured into molds, such as steel molds, poured into water, or quenched with a metal roller to make solid forms. In further embodiments, the forms may be annealed.

The glass may then be cerammed. In various embodiments, ceramming the glass may comprise one or more heating stages. A first stage may comprise a nucleation ramp, i.e., a time interval during which the material is heated slowly over a temperature range, or a nucleation hold, i.e., a time interval over which the material is held at a first isothermal temperature. A second stage may be a hold stage, i.e., a time interval over which the material is held at a second isothermal temperature.

It is within the ability of one skilled in the art to determine the appropriate method and conditions for ceramming, such as, for example, the number of heating stages, firing conditions including equipment, temperature, and duration, to achieve a glass-ceramic material, depending in part upon the size and composition of the glass-ceramic material.

By way of example, the ceramming may comprise two heating stages, which may include heating the glass material at a rate of about 7° C./min to about 600° C., heating the material from about 600° C. to about 650° C. at about 0.8° C./min (nucleation ramp), and further heating the material at about 7° C./min from about 650° C. to a second hold temperature. In various exemplary embodiments, the second hold temperature may range from about 900° C. to 1100° C., such as from about 950° C. to 1050° C., or from about 1055° C. to 1100° C. In various embodiments, the total ceramming time may range from about 2 hours to 32 hours.

In various embodiments, the material may optionally be melted and/or cerammed in an inert or reducing atmosphere, such as a nitrogen atmosphere.

In additional embodiments, the methods of making tungsten-titanium-phosphate glass-ceramic materials may comprise crushing the quenched glass. In further embodiments, the crushed material may be pressed into a porous body, heated to ceram the material and sintered to form a dense body, or the crushed material may be cerammed in a hot press or spark plasma sintering system and sintered to a dense body.

In additional embodiments, the methods of making tungsten-titanium-phosphate materials may comprise crushing the cerammed material or crystalline material. In further embodiments, the crushed material may be sintered to a dense body.

Unless otherwise indicated, all numbers used in the specification and claims are to be understood as being modified in all instances by the term “about,” whether or not so stated. It should also be understood that the precise numerical values used in the specification and claims form additional embodiments according to the disclosure. Efforts have been made to ensure the accuracy of the numerical values disclosed in the Examples. Any measured numerical value, however, can inherently contain certain errors resulting from the standard deviation found in its respective measuring technique.

Other embodiments of the disclosure will be apparent to those skilled in the art from consideration of the specification and practice of the invention disclosed herein. It is intended that the specification and examples be considered as exemplary only, with a true scope and spirit of the invention being indicated by the claims.

### EXAMPLES

### Example 1

Various tungsten-titanium-phosphate materials were made by mixing tungsten trioxide, titanium dioxide, titanium (III) oxide, and ammonium phosphate powders to give the batch compositions shown in Table 1. The batch ingredients were mixed in a Turbula® mixer, and then melted in covered silica crucibles in an electrically-fired furnace at 1525° C. for 2 hours. The melts were poured into steel molds to make patties. The patties were transferred to an annealing oven operating at 600° C. The patties were black when removed from the annealing oven. Samples of each composition were chemically analyzed, and the results are set forth in Table 1. As seen in Table 1, several percent loss of P₂O₅ typically occurred, and several percent SiO₂ was typically gained from the silica crucible.

The annealed material was then heated at a rate of 7° C./min to 600° C. and from 600° C. to 650° C. at about 0.8° C./min. The material was further heated from 650° C. at 7° C./min to a second hold temperature. The second hold temperature and hold time for each sample are set forth in Table 1.

The thermoelectric properties of the samples are also set forth in Table 1. Electrical conductivity and Seebeck coefficient were measured on samples, 2.5-3 mm wide×1.5-2 mm thick×12-14 mm long, using a ZEM instrument. Measurements were made over the temperature range of approximately 460K to 1050K.

The power factor (PF) was calculated from the ZEM data as PF=S²*σ, where S is the Seebeck coefficient and σ is the electrical conductivity. Thermal diffusivity measurements were made by the laser flash method on samples 10 mm×10 mm×1.5-2 mm thick. Measurements were converted to thermal conductivity (K) using the standard formula, κ=Diffusivity*Cp*density (at temperature), where Cp is heat capacity. Measurements were made within the temperature range 560K to 1050K. The figure of merit, ZT, was calculated from the equation: ZT=PF*T/κ, where T is the temperature in degrees K, PF is the power factor at temperature T, and κ is the thermal conductivity at temperature T.

TABLE 1

| | A | B | C | D | E | F | G | H | I |
|---|---|---|---|---|---|---|---|---|---|
| Batch Mol % | | | | | | | | | |
| WO3 | 23.5 | 31.0 | 28.5 | 47.5 | 33.5 | 42.5 | 57.5 | 50.0 | 60.0 |
| TiO2 | 31.0 | 31.0 | 28.5 | 17.5 | 33.5 | 27.5 | 12.5 | 30.0 | 20.0 |
| P2O5 | 45.5 | 38.0 | 43.0 | 35.0 | 33.0 | 30.0 | 30.0 | 20.0 | 20.0 |
| Actual Mol % | | | | | | | | | |
| WO3 | 23.6 | 28.5 | 28.5 | 43.7 | 32.3 | 39.1 | 52.1 | 46.3 | 55.1 |
| TiO2 | 28.1 | 29.3 | 29.7 | 16.6 | 33.5 | 25.7 | 12.3 | 27.1 | 17.8 |
| P2O5 | 36.4 | 32.7 | 28.9 | 29.0 | 27.4 | 26.0 | 24.0 | 17.4 | 17.0 |
| SiO2 | 11.9 | 9.5 | 12.9 | 10.7 | 6.8 | 9.2 | 11.6 | 9.3 | 10.1 |
| Ceram: | 950 C.-2 h | 1000 C.-2 h | 950 C.-2 h | 1000 C.-2 h | 950 C.-2 h | 1000 C.-8 h | 1050-2 h | 950 C.-2 h | 950 C.-2 h |
| Properties (560K) | | | | | | | | | |
| Electrical conductivity (S/m) | 2042 | 2000 | 356 | 787 | 3644 | 2427 | 262 | 13000 | 17600 |
| Seebeck coefficient (μV/K) | −26.6 | −32.0 | −49.4 | −26.8 | −25.8 | −44.6 | −44.7 | −27.8 | −30.5 |
| Power Factor (W/m-K\hat{ }2) | 1.4E−06 | 2.0E−06 | 8.7E−07 | 5.7E−07 | 2.4E−06 | 4.8E−06 | 5.2E−07 | 1.0E−05 | 1.6E−05 |
| Thermal Conductivity (W/m-K) | 1.768 | 2.241 | 1.917 | 2.453 | 2.378 | 2.861 | 1.767 | x | 3.041 |
| ZT | 4.6E−04 | 5.1E−04 | 2.5E−04 | 1.3E−04 | 5.7E−04 | 9.6E−04 | 1.7E−04 | x | 3.0E−03 |
| Properties (1050K) | | | | | | | | | |
| Electrical conductivity (S/m) | 2001 | 2740 | 1040 | 2100 | 3326 | 5164 | 1580 | 9300 | 15100 |
| Seebeck coefficient (μV/K) | −52.4 | −55.8 | −81 | −52.5 | −45.2 | −68.8 | −67.3 | −49.7 | −52.2 |
| Power Factor (W/m-K\hat{ }2) | 5.5E−06 | 8.6E−06 | 6.9E−06 | 5.8E−06 | 6.8E−06 | 2.4E−05 | 7.2E−06 | 2.3E−05 | 4.1E−05 |
| Thermal Conductivity (W/m-K) | 2.083 | 2.726 | 2.138 | 2.380 | 2.843 | 2.404 | 1.834 | x | 3.331 |
| ZT | 2.7E−03 | 3.3E−03 | 3.3E−03 | 2.5E−03 | 2.5E−03 | 1.1E−02 | 4.1E−03 | x | 1.3E−02 |

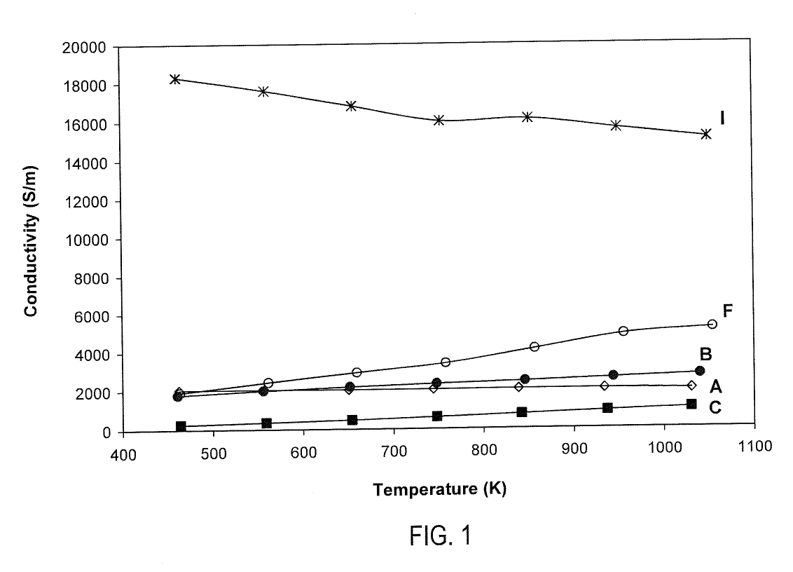

FIG. 1 shows electrical conductivity as a function of temperature for materials A, B, C, F, and I from Table 1. As seen in FIG. 1, the behavior of the materials ranges from semiconducting to metallic as seen by the increase or decrease of the electrical conductivity with temperature, respectively. Overall, electrical conductivity is relatively constant over the temperature range. Electrical conductivities greater than 18000 S/m were measured for Example I.

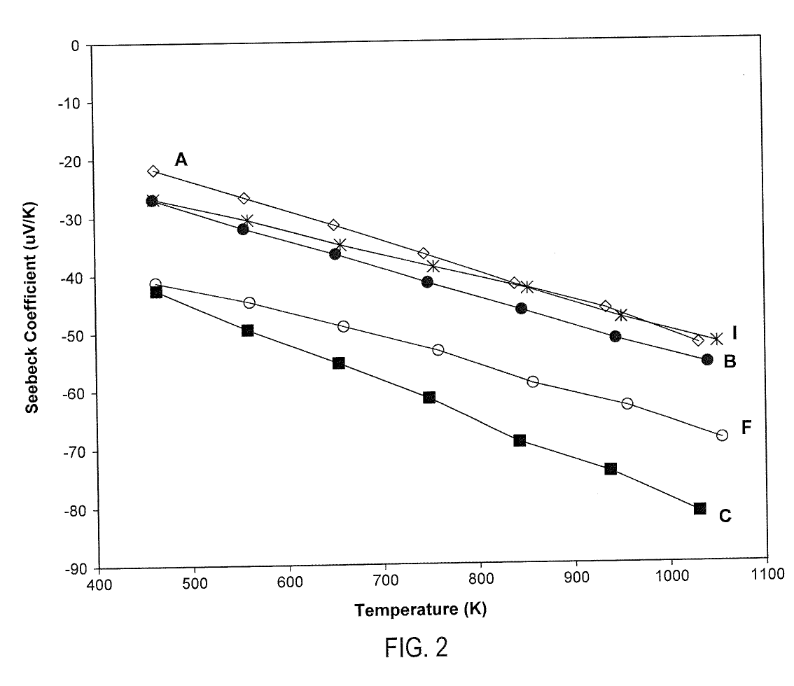

FIG. 2 shows Seebeck coefficients as a function of temperature for materials A, B, C, F, and I from Table 1. Seebeck coefficients for the materials of the disclosure are negative, indicating n-type behavior. The range of Seebeck coefficients is from approximately −20 μV/K to −85 μV/K.

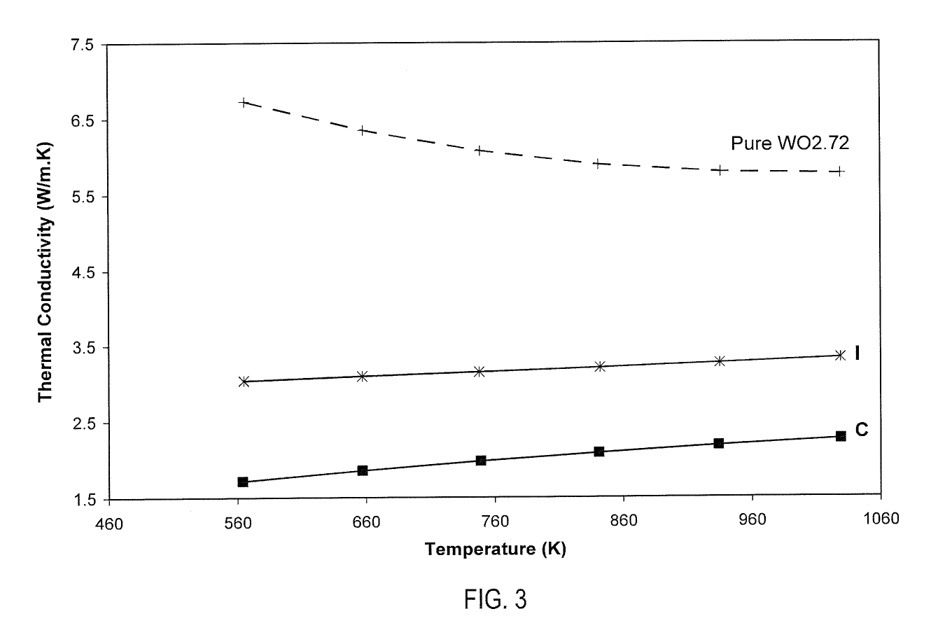

FIG. 3 shows thermal conductivities as a function of temperature for materials C and I from Table 1. Thermal conductivities for these materials are generally less than 3.5 W/m·K. This compares favorably to the conductivity of pure WO_{2.72}, which is greater than 5.5 W/m·K over the temperature range 560K to 1030K.

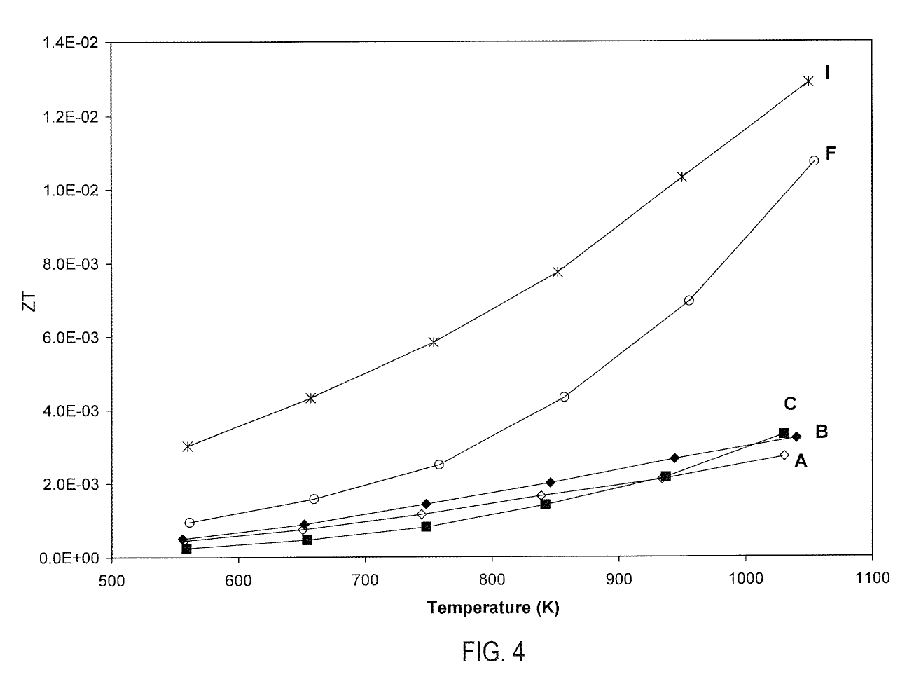

FIG. 4 shows figures-of-merit, ZT, for materials A, B, C, F, and I from Table 1. Materials F and I provided the highest ZTs, 0.011 to 0.013, respectively at 1050K.

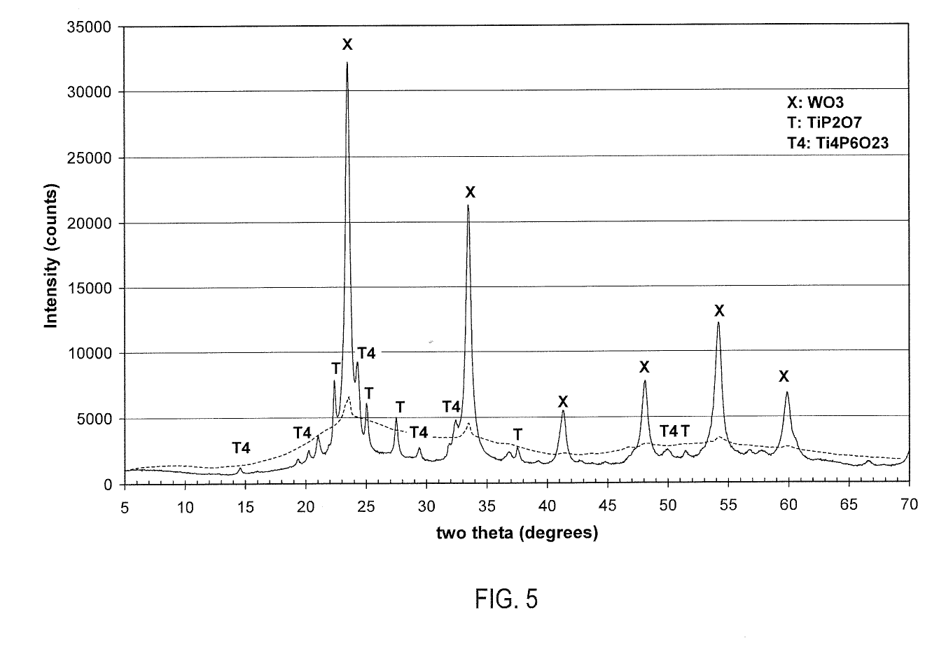

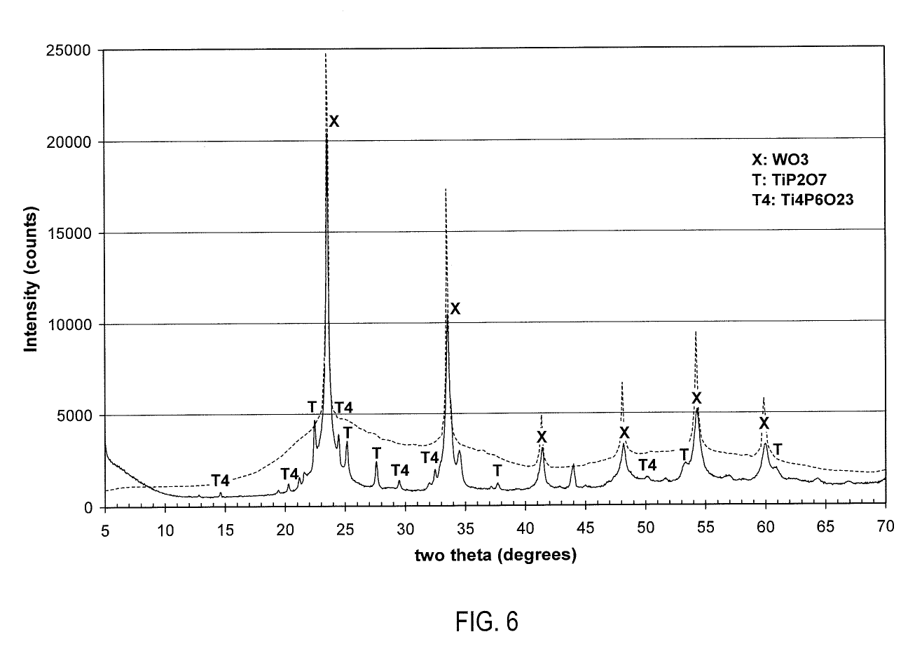

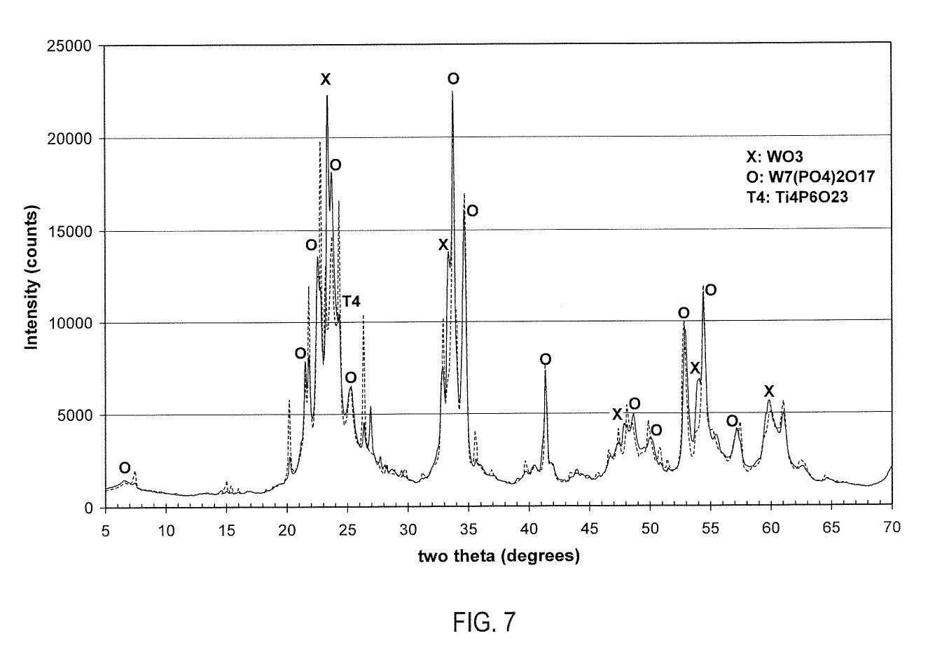

FIGS. 5-7 show x-ray diffraction patterns recorded from materials C, F, and I, respectively, after annealing (dotted line) and after ceramming under the conditions shown in Table 1 (solid line). Materials with analyzed P₂O₅ concentrations greater than approximately 29 actual mol %, such as material C, tend to be mostly amorphous after annealing. Compositions with slightly less P₂O₅, such as material F, tend to contain glass and WO₃ crystals. Compositions with much less P₂O₅, such as material I, tend to crystallize on cooling from the melt. Samples which crystallize directly from the melt can be used as thermoelectric materials with or without further heat treatment. As an example, material I, as-crystallized on cooling from the melt and prior to ceramming, had an electrical conductivity of 23200 S/m, a Seebeck coefficient of −24.6 uV/K, and a PF of 1.4E-05 W/m·K² at 560K; and an electrical conductivity of 21700 S/m, a Seebeck coefficient of −40.7 uV/K, and a PF of 3.6E-05 W/m·K² at about 1050K. Cerammed materials are substantially crystalline as shown by the XRD patterns.

### Example 2

Various tungsten-titanium-phosphate materials comprising dopants were made by the same procedure set forth in Example 1. In this example, Na₂O, K₂O and Rb₂O were added to compositions like that of C, F, and I in Table 1. The alkalis were added to the batch material as the carbonates. The components and their amounts for the doped materials are set forth in Table 2. Samples of each annealed composition were chemically analyzed, and the results are set forth in Table 2. As in Example 1, Table 2 shows that several percent loss of P₂O₅ typically occurred, and several percent silica was typically gained from the silica crucible.

The annealed materials were heated at a rate of 7° C./min to 600° C. and from 600° C. to 650° C. at about 0.8° C./min. The materials were further heated from 650° C. at 7° C./min to a second hold temperature of 950° C. for a hold time of 2 hours as set forth in Table 2.

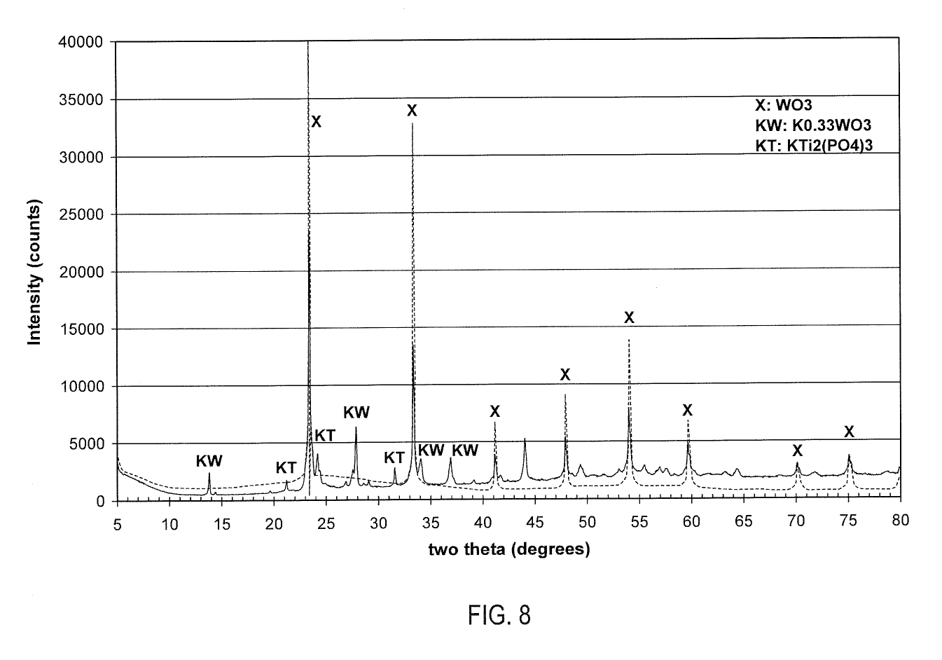

FIG. 8 shows the x-ray diffraction patterns recorded from material Q after annealing (dotted line) and after ceramming at 950° C. for 2 hours in nitrogen atmosphere (solid line). As seen from FIG. 8, the annealed material contains some glassy phase and WO₃ crystals, while the cerammed materials contains WO₃, K_{0.33}WO₃ and KTi₂(PO4)₃ crystalline phases.

TABLE 2

| | J | K | L | M | N | O | P | Q | R |
|---|---|---|---|---|---|---|---|---|---|
| Batch Mol % | | | | | | | | | |
| WO3 | 27.5 | 27.5 | 27.5 | 40.4 | 40.4 | 40.4 | 55.8 | 55.8 | 55.8 |
| TiO2 | 27.5 | 27.5 | 27.5 | 26.1 | 26.1 | 26.1 | 18.6 | 18.6 | 18.6 |
| P2O5 | 41.5 | 41.5 | 41.5 | 28.5 | 28.5 | 28.5 | 18.6 | 18.6 | 18.6 |
| Na2O | 3.4 | 0.0 | 0.0 | 5.0 | 0.0 | 0.0 | 7.0 | 0.0 | 0.0 |
| K2O | 0.0 | 3.4 | 0.0 | 0.0 | 5.0 | 0.0 | 0.0 | 7.0 | 0.0 |
| Rb2O | 0.0 | 0.0 | 3.4 | 0.0 | 0.0 | 5.0 | 0.0 | 0.0 | 7.0 |
| Actual Mol % (norm.) | | | | | | | | | |
| WO3 | 25.5 | 26.1 | 27.9 | 38.2 | 38.2 | 38.4 | 52.1 | 52.5 | 53.0 |
| TiO2 | 26.0 | 26.4 | 27.8 | 25.1 | 25.1 | 25.1 | 17.2 | 18.1 | 17.4 |
| P2O5 | 33.1 | 35.2 | 36.6 | 25.4 | 25.4 | 25.5 | 16.2 | 16.3 | 17.3 |
| Na2O | 3.6 | 0.0 | 0.0 | 4.4 | 0.0 | 0.0 | 6.0 | 0.0 | 0.0 |
| K2O | 0.0 | 2.5 | 0.0 | 0.0 | 3.5 | 0.0 | 0.0 | 4.7 | 0.0 |
| Rb2O | 0.0 | 0.0 | 2.0 | 0.0 | 0.0 | 2.9 | 0.0 | 0.0 | 3.8 |
| SiO2 | 11.8 | 9.8 | 5.7 | 6.8 | 7.8 | 8.0 | 8.6 | 8.4 | 8.5 |
| Ceram: | 950 C.-2 h | 950 C.-2 h | 950 C.-2 h | 950 C.-2 h | 950 C.-2 h | 950 C.-2 h | 950 C.-2 h | 950 C.-2 h | 950 C.-2 h |
| Properties (560K) | | | | | | | | | |
| Electrical conductivity (S/m) | 127 | | 914 | 85 | 704 | 1560 | 1740 | 691 | 519 |
| Seebeck coefficient (μV/K) | −23.0 | | −22.9 | −38.0 | −37.2 | −37.8 | −50.3 | −78.5 | −55.1 |
| Power Factor (W/m-K\hat{ }2) | 6.7E−08 | | 4.8E−07 | 1.2E−07 | 9.7E−07 | 2.2E−06 | 4.4E−06 | 4.3E−06 | 1.6E−06 |
| Properties (1050K) | | | | | | | | | |
| Electrical conductivity (S/m) | 832 | | 1249 | 293 | 1470 | 3330 | 8010 | 4770 | 2110 |
| Seebeck coefficient (μV/K) | −47.5 | | −42.3 | −71.8 | −61.6 | −69.8 | −72.1 | −80.5 | −79.8 |
| Power Factor (W/m-K\hat{ }2) | 1.9E−06 | | 2.2E−06 | 1.5E−06 | 5.6E−06 | 1.6E−05 | 4.2E−05 | 3.1E−05 | 1.4E−05 |

What is claimed is:

1. A method for generating electricity from waste heat, said method comprising applying a module comprising tungsten-titanium-phosphate material to a source of waste heat,
wherein the tungsten-titanium-phosphate material comprises about 20 to 60 actual mol % WO₃, about 10 to 40 actual mol % TiO₂, and about 15 to 40 actual mol % P₂O₅, and
wherein the tungsten-titanium-phosphate material has a has a figure-of-merit (ZT) of at least about 0.001 at 1050K.

2. The method of claim 1, wherein the tungsten-titanium-phosphate material is a glass-ceramic material.

3. The method of claim 1, wherein the tungsten-titanium-phosphate material is comprised of about 20 to 24 actual mol % WO₃.

4. The method of claim 1, wherein the tungsten-titanium-phosphate material is comprised of about 15 to 24 actual mol % P₂O₅.

5. The method of claim 1, wherein the tungsten-titanium-phosphate material has a figure-of-merit (ZT) of at least about 0.01 at 1050K.

6. The method of claim 1, wherein the tungsten-titanium-phosphate material has a Seebeck coefficient (S) of at least about 40 μV/K, absolute, at 1050K.

7. The method of claim 1, wherein the tungsten-titanium-phosphate material has an electrical conductivity of at least about 1000 S/m at 1050K.

8. The method of claim 1, wherein the tungsten-titanium-phosphate material has a thermal conductivity of less than about 5 W/m·K at 1050K.

9. The method of claim 1, wherein the tungsten-titanium-phosphate material has a power factor of at least about 1.0E-06 W/m·K² at 1050K.

10. The method of claim 1, wherein the tungsten-titanium-phosphate material further comprises silica and/or at least one dopant.

11. The method of claim 1, wherein the tungsten-titanium-phosphate material further comprises at least one dopant chosen from aluminum, alkali metals and transition metals.

12. The method of claim 1, wherein the tungsten-titanium-phosphate material further comprises at least one dopant chosen from Li, Na, K, Rb, Cs, V, Cr, Mn, Fe, Co, Ni, Cu, Mo, Nb, Al and Zr.

13. A tungsten-titanium-phosphate material comprising about 20 to 60 actual mol % WO₃, about 10 to 40 actual mol % TiO₂, and about 15 to 40 actual mol % P₂O₅;
wherein said tungsten-titanium-phosphate material further comprises silica and/or at least one dopant; and
wherein said tungsten-titanium-phosphate material has a figure-of-merit (ZT) of at least about 0.001 at 1050K.

14. The tungsten-titanium-phosphate material of claim 13, wherein the material is a glass-ceramic material.

15. The tungsten-titanium-phosphate material of claim 13, wherein the material is comprised of about 20 to 24 actual mol % WO₃.

16. The tungsten-titanium-phosphate material of claim 13, wherein the material is comprised of about 15 to 24 actual mol % P₂O₅.

17. The tungsten-titanium-phosphate material of claim 13, wherein the material has a figure-of-merit (ZT) of at least about 0.01 at 1050K.

18. The tungsten-titanium-phosphate material of claim 13, wherein the material has a Seebeck coefficient (S) of at least about 40 μV/K, absolute, at 1050K.

19. The tungsten-titanium-phosphate material of claim 13, wherein the material has an electrical conductivity of at least about 1000 S/m at 1050K.

20. The tungsten-titanium-phosphate material of claim 13, wherein the material has a thermal conductivity of less than about 5 W/m·K at 1050K.

21. The tungsten-titanium-phosphate material of claim 13, wherein the material has a power factor of at least about 1.0E-06 W/m·K² at 1050K.

22. The tungsten-titanium-phosphate material of claim 13, wherein the material further comprises silica and/or at least one dopant.

23. The tungsten-titanium-phosphate material of claim 13, wherein the material further comprises at least one dopant chosen from aluminum, alkali metals and transition metals.

24. The tungsten-titanium-phosphate material of claim 13, wherein the material further comprises at least one dopant chosen from Li, Na, K, Rb, Cs, V, Cr, Mn, Fe, Co, Ni, Cu, Mo, Nb, Al and Zr.

25. A method of making tungsten-titanium-phosphate glass-ceramic material, said method comprising:
mixing batch ingredients to form a batch mixture;
melting the batch mixture;
quenching the melted batch mixture to glass; and
ceramming the glass; wherein
the tungsten-titanium-phosphate glass-ceramic material comprises about 20 to 60 actual mol % WO₃, about 10 to 40 actual mol % TiO₂, and about 15 to 40 actual mol % P₂O₅; and
the tungsten-titanium-phosphate glass-ceramic material has a figure-of-merit (ZT) of at least about 0.001 at 1050K.

26. The method of claim 25, wherein the tungsten-titanium-phosphate glass-ceramic material is comprised of about 20 to 24 actual mol % WO₃.

27. The method of claim 25, wherein the tungsten-titanium-phosphate glass-ceramic material is comprised of about 15 to 24 actual mol % P₂O₅.

28. The method of claim 25, wherein the tungsten-titanium-phosphate glass-ceramic material has a figure-of-merit (ZT) of at least about 0.01 at 1050K.

29. The method of claim 25, wherein the tungsten-titanium-phosphate glass-ceramic material has a Seebeck coefficient (S) of at least about 40 μV/K, absolute, at 1050K.

30. The method of claim 25, wherein the tungsten-titanium-phosphate glass-ceramic material has an electrical conductivity of at least about 1000 S/m at 1050K.

31. The method of claim 25, wherein the tungsten-titanium-phosphate glass-ceramic material has a thermal conductivity of less than about 5 W/m·K at 1050K.

32. The method of claim 25, wherein the tungsten-titanium-phosphate glass-ceramic material has a power factor of at least about 1.0E-06 W/m·K² at 1050K.

33. The method of claim 25, wherein the tungsten-titanium-phosphate glass-ceramic material further comprises silica and/or at least one dopant.

34. The method of claim 25, wherein the tungsten-titanium-phosphate glass-ceramic material further comprises at least one dopant chosen from aluminum, alkali metals and transition metals.

35. The method of claim 25, wherein the tungsten-titanium-phosphate glass-ceramic material further comprises at least one dopant chosen from Li, Na, K, Rb, Cs, V, Cr, Mn, Fe, Co, Ni, Cu, Mo, Nb, Al and Zr.

36. The method of claim 25, wherein ceramming the glass comprises two heating stages.

37. The method of claim 25, wherein ceramming the glass comprises two heating stages, and wherein the second heating stage has a hold temperature ranging from about 900° C. to 1100° C.

38. The method of claim 25, wherein ceramming the glass comprises two heating stages, and wherein the second heating stage has a hold temperature ranging from about 1010° C. to 1100° C.

39. The method of claim 25, wherein the glass is melted and/or cerammed in an inert or reducing atmosphere.

40. The method of claim 25, wherein the method further comprises crushing the quenched glass.

41. The method of claim 40, wherein the method further comprises ceramming the crushed material and then sintering the cerammed material to form a dense body.

42. The method of claim 40, wherein the method further comprises sintering the crushed material to form a dense body and then ceramming the dense body.

43. The method of claim 25, wherein the method further comprises crushing the cerammed material.

44. The method of claim 43, wherein the method further comprises sintering the crushed material to form a dense body.
